(19) United States
(12) Patent Application Publication
(10) Pub. No.: US 2012/0168392 A1
(43) Pub. Date: Jul. 5, 2012

(54) Racking Systems

(75) Inventor: David Franklin-Lees, Denham Green (GB)

(73) Assignee: MODE-AL LTD, Uxbridge Middlesex (GB)

(21) Appl. No.: 13/394,719

(22) PCT Filed: Sep. 6, 2010
(86) PCT No.: PCT/GB2010/001682

§ 371 Date: Mar. 7, 2012

(30) Foreign Application Priority Data
Sep. 8, 2009 (GB) 0915688.6

(51) Int. Cl. H05K 7/14

(52) U.S. Cl. 211/26

(57) ABSTRACT

The present invention is directed toward improvements in racking systems, and in particular to a racking system which can be constructed to accommodate a variety of different sized items of equipment. The racking system includes a plurality of parallel vertical support members, each provided with a series of slots spaced apart along at least a section of the length of support member. The support members each include a locking member movable relative to the, slots between an unlocked position, in which the slots are open to allow a mounting element to be inserted in or removed from the slots, and a locked position in which mounting elements located position in which mounting elements located in any of the slots are restrained therein.

The present invention relates to improvements in racking systems, and in particular to a racking system which can be constructed to accommodate a variety of different sized items of equipment.

In many fields, such as in broadcasting, telecommunications, entertainment and security, it is a common requirement to create a stack of equipment, such as audio equipment, display screens or television monitors. Often, for example in outside broadcasting, it is also necessary to be able to create temporary stacks of equipment.

Such a stack was relatively easy to achieve with bulky cathode ray tube (CRT) monitors. The dimensions of these, and many other items of rack mountable equipment, have been standardised so that they can be mounted in 19 inch (480 mm) racks, which is a standardised frame designed for mounting multiple items of equipment. A rack unit (U) is a unit of measure which describes the height of equipment intended for mounting in a 19 inch rack. A 1 U piece of equipment is of a width which can be mounted across a 19 inch width rack and having a standardised height of 1.75 inches (44.45 mm); a 3 U piece of equipment has the same width as a 1 U piece of equipment but has a height of 3×1.75 inches; a half rack 2 U piece of equipment has a height of 2×1.75 inches and will occupy half the width of a 19 inch rack.

However, as a result of the recent use of plasma and LCD technology, many modern monitors and screens are now considerably larger and flatter than previously and their dimensions preclude the possibility of directly stacking them on top of each other unaided. It is also impractical to mount these newer monitors in traditional 19 inch racks (either on shelves in the racks or attached to mounting panels affixed to the racks) as the type of equipment that can be adapted to fit a traditional 19 inch rack is limited. Other disadvantages with the traditional racks include the time taken to assemble and disassemble them, as well as the space taken up by them, particularly as they cannot be ‘flat-packed’.

It is therefore an object of the invention to provide a flexible racking system which can accommodate a variety of different types and sizes of equipment, including both standard and non-standard sized units. Another object is to provide a system which facilitates the quick change of individual items of mounted equipment in the case of failure, upgrade, or reconstruction. A further object is to provide a system which can be quickly and easily assembled and disassembled for temporary usage.

According to the invention there is therefore provided a racking system comprising a plurality of parallel vertical support members, each provided with a series of slots spaced apart along at least a section of the length of support member, the support members each comprising a locking member movable relative to the slots between an unlocked position, in which the slots are open to allow a mounting element to be inserted in or removed from the slots, and a locked position in which mounting elements located position in which mounting elements located in any of the slots are restrained therein.

The racking system of the present invention thus enables the rapid construction of a stack of equipment, including both standard 19 inch and non-standard items, with no additional fixings required to securely lock the equipment into position.

The racking system can also be ‘flat-packed’ for economic transportation.

The locking system facilitates both rapid assembly and disassembly and as each support member has its own separately activated locking member, this provides a twin fail-safe system which prevents the accidental release of the equipment.

Preferred embodiments of the invention will now be described, by way of example only, with reference to the accompanying drawings in which:

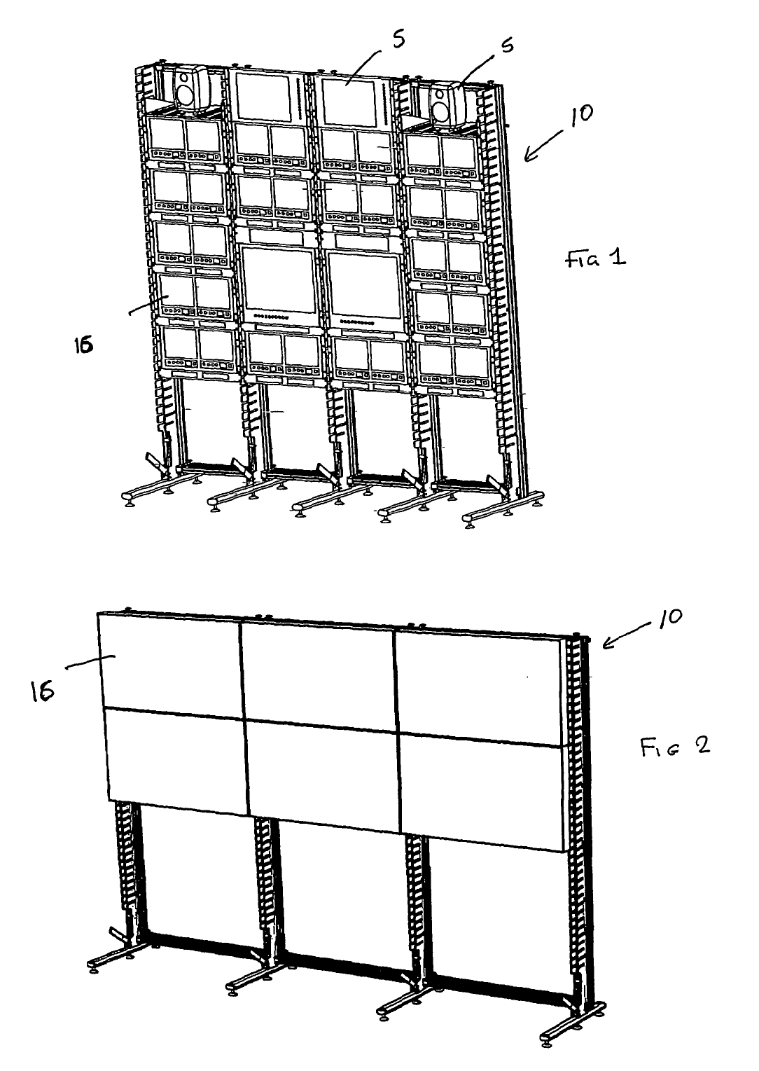

FIG. 1 is a pictorial view of a stack of audio visual equipment constructed using a racking system of the present invention;

FIG. 2 is a pictorial view of the racking system of FIG. 1 on which different sized audio visual equipment from that illustrated in FIG. 1 has been mounted;

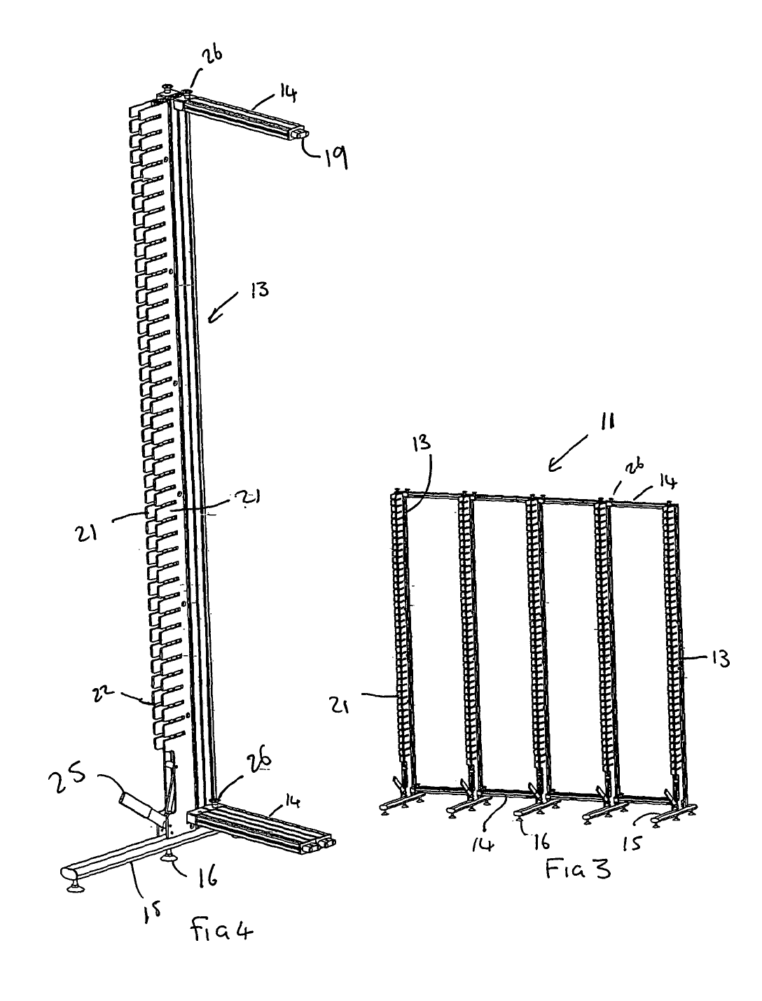

FIG. 3 is a pictorial view of a support structure of the racking system of FIG. 1;

FIG. 4 is a pictorial view of a support member used to construct the support structure of FIG. 3;

FIG. 5 is a pictorial view of a support structure with a section removed from one of the support members to illustrate the locking system;

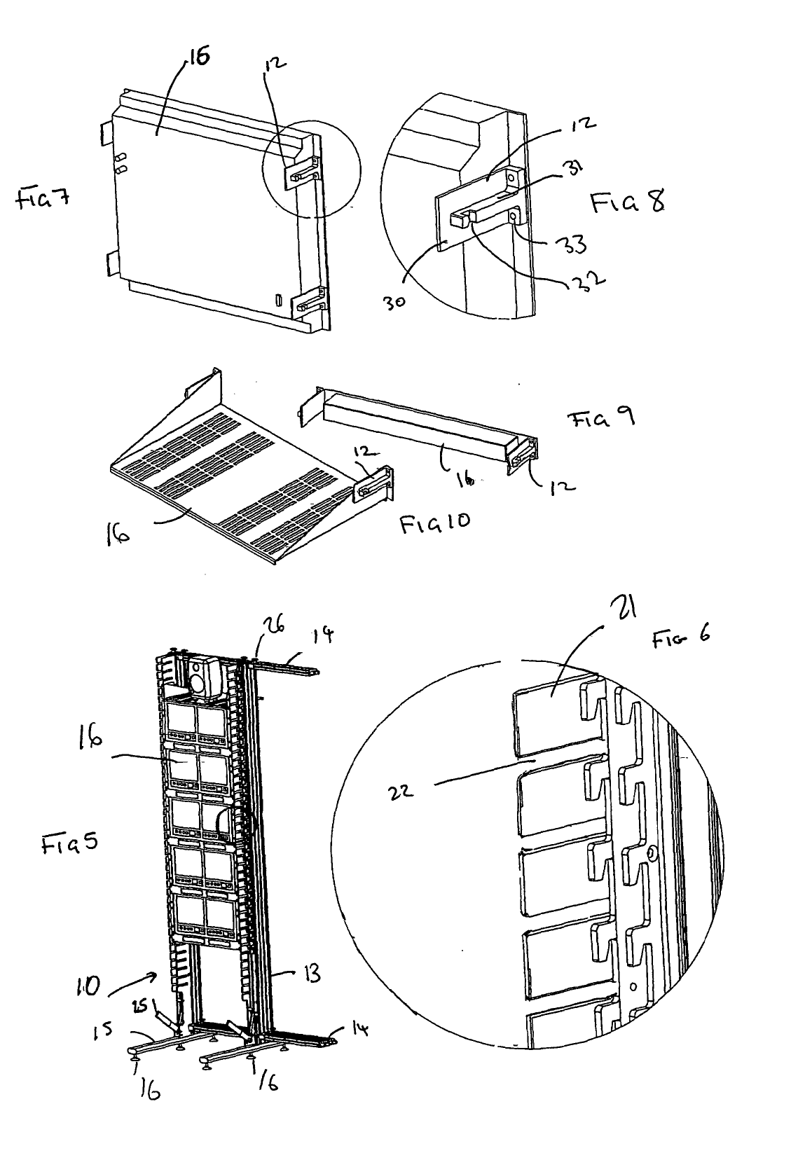

FIG. 6 is enlarged section of the locking system of the racking system of FIG. 1;

FIG. 7 is a pictorial view of an item of equipment with mounting members attached;

FIG. 8 is an enlarged view of a section of FIG. 7 showing the mounting member in greater detail;

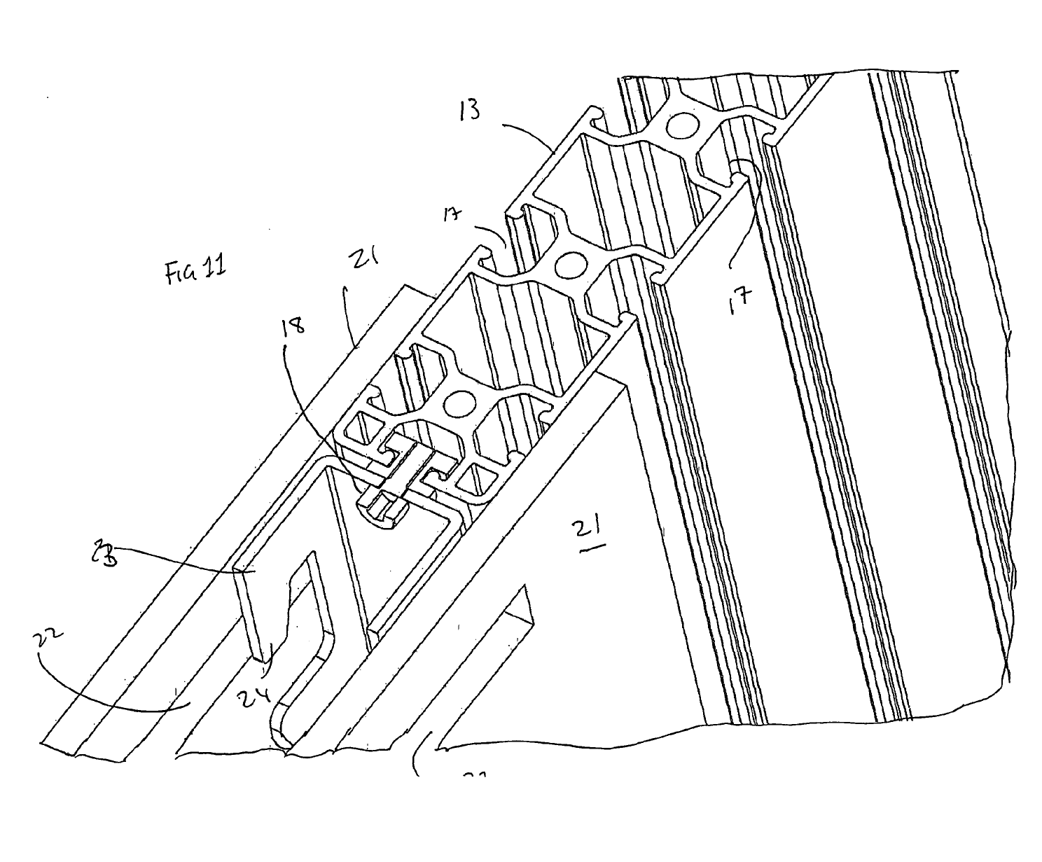

FIGS. 9 and 10 are pictorial views of the mounting member of FIG. 7 attached to different items; and

FIG. 11 is a horizontal cross-section through the support member of FIG. 4.

FIGS. 1 and 2 illustrate the mounting of a variety of equipment 16 of different dimensions on a racking system 10 of the present invention.

The racking system 10 comprises a support structure 11 (FIG. 3) which is constructed from a plurality of vertical support members 13 (FIG. 4). The number of support members 13 can be varied according to the size of stack required. The minimum number which can be used is two, and there is no limit on the maximum number.

The support members 13 are preferably extruded metal sections incorporating a number of longitudinal channels 17 for receiving fixings 18 as shown in detail in FIG. 11. The support members 13 are preferably self supporting with a stabilising member 15 extending horizontally from a lower end of each support member 13. Optionally, a plurality of feet 16 may be attached to the base of the stabilising members 15.

If the racking system 10 is intended to be permanent, the support members 13 may be attached to a wall or other permanent surface rather than free standing.

Each support member 13 is preferably connected to at least one adjacent support member by means of one or more horizontal cross-members 14, preferably at the top and bottom. The support members 13 and cross-members 14 are provided with means for attachment. For example this may comprise apertures located in the support members 13 for receiving a spigot 19 located on the ends of the cross member 14 to provide a push fit connection. For additional safety, pins or other locking means 26 may be used to secure the spigots 19 in the apertures.

The cross members 14 enable the pairs of support members 13 to be joined in a manner that allows the distance between the support members 13 to be varied. Cross members 14 of different lengths may be used between adjacent pairs of support members 13. The racking system 10 may include a number of sets of different fixed length cross members 14, or the cross members 14 may be telescopic.

The support members 13 further comprise an elongate slotted panel 21 extending along the length of each support member 13. More preferably, two parallel slotted panels 21 are attached to each support member 13, such that equipment 16 can be attached to each side of the support member 13. Each slotted panel 21 is provided with a series of spaced apart slots 22 that extend laterally (horizontally or at a downward angle) into the panel member 21 along its length to form a comb-like structure. The slotted panels 21 are preferably laser cut from sheet metal.

The support members 13 also comprise a locking member 23 extending along the length of each support member 13. This is positioned adjacent to the slotted panels 21 and preferably comprises a plurality of spaced apart downwardly directed projections 24, the number of which corresponds to the number of slots 22 in the slotted panels 21. Preferably the locking member 23 is a substantially U shaped extruded member have two parallel rows of projections 24 which is located between the two slotted panels 21.

The locking member 23 is slidably attached to the support member 13 by suitable fixings 18 (see FIG. 11), so as to be moveable relative to the slotted panels 21 in a vertical direction. The movement is preferably effected by a lever 25 or other actuator, positioned at the base of the support member 13.

The racking system 10 preferably further comprises a plurality of mounting members 12, which can be fitted either directly to items of equipment or to shelves. FIGS. 7 to 10 show one embodiment of mounting member 12 attached to various items of equipment 18. The mounting members 12 comprise a back-plate 30, to which is attached a substantially T-shaped element 31. The stem of the T-shaped element 31 must be of a size and shape so that it can be inserted into the slots 22 in the support members 13. In the stem of the T-shaped element 31 is a recess, notch or groove 32 which is shaped and positioned to receive an end of the projections 24 of the locking member 23.

The mounting members 12 further comprise suitable means for attachment to the equipment 16. A non-limiting example of such means comprise holes 33 drilled through the cross piece of the T-shaped element that enable it to be screwed onto the equipment 16. The actual shape of the mounting member 12 can be varied from that illustrated, but must be capable of being attached to equipment 16, and be of a size and shape that will slide easily into the slots 22.

The mounting members 12 can be manufactured from any suitable material. A non-limiting example of a suitable material is polyphthalamide (also known as PPA or high performance polyamide and sold under the trade mark Grivory™. Preferably, the manufacturing process used to form the mounting members 12 is injection moulding. The combination of manufacturing process and material of injection moulded polyphthalamide results in a tough and low cost component with a high durability.

In use, the preferred basic support structure 11 is constructed by connecting a plurality of support members 13 with pairs of cross members 14. The width between each pair of support member 13 is selected according to the width of the equipment 16 to be mounted on the system 10. At least one mounting member 12 is fitted to each (usually) vertical side or end of a piece of equipment 16. The equipment 16 is then placed between two support members 13. The desired height is selected by inserting the stem of the T-shaped elements 31 of the respective mounting members 12 into horizontally aligned slots 22 in the opposing slotted panels 21. When the equipment 16 is in its correct position, the back-plate 30 of the mounting member 12 preferably sits flush against the front end of the slotted panel 21.

Once the equipment 16 to be mounted has been positioned in the racking system 10 as desired, it is locked into place by moving the levers 25 on each support member 13 from their unlocked position to the locked position. This causes the projections 24 of the locking members 23 to move down and, where there are mounting members present in any of the slots 22, the corresponding projections 24 slide into the grooves 32 on the mounting members 12 preventing restraining them within the slots 22. Individual items of equipment 16 can be subsequently removed, by moving the levers 25 on each support member 13 on either side of the equipment 16 in question from their locked position to the unlocked position, so that the projections 24 of the locking members 23 move upwardly, withdrawing from the grooves 32. This enables individual items of equipment to be replaced, repaired or serviced easily. Accidental unlocking of the locking system is prevented, since two actions are required to unlock the equipment 16, namely separately unlocking the locking member 23 on each support member 13.

The racking system 10 is disassembled by carrying out the assembly process in. The ability to disassemble the vertical support members 13 and the horizontal cross members 14 of the support structure 11 enables the structural components of the racking system 10 to be transported in a space efficient and economically efficient manner.

1. A racking system, said system comprising, a plurality of parallel vertical support members, each provided with a series of slots spaced apart along at least a section of the length of support member, the support members each comprising a locking member movable relative to the slots between an unlocked position, in which the slots are open to allow a mounting element to be inserted in or removed from the slots, and a locked position yin which mounting elements located position in which mounting elements located in any of the slots are restrained therein.

2. A racking system as claimed in claim 1, wherein adjacent pairs of support members are joined together by one or more horizontal cross members.

3. A racking system as claimed in claim 2, wherein the cross members are telescopic.

4. A racking system as claimed in claim 1, further comprising a stabilizing member attached to a base of each support member.

5. A racking system as claimed in claim 1, in which each support member has two parallel series of slots, arranged with one on either side of the locking member.

6. A racking system as claimed in claim 1, wherein the locking member comprises a number of projections corresponding to a number of slots.

7. A racking system as claimed in claim 1, further comprising a lever to actuate the locking member.

8. A racking system as claimed in claim 1, further comprising a plurality of mounting members each comprising a mounting element and means for attachment to items of equipment.

9. A racking system as claimed in claim 8 wherein the mounting element is an elongate rail attached to a back-plate.

10. A racking system as claimed in claim 9, wherein the elongate protrusion comprises an indent.

11. (canceled)
